(19) United States
(12) Patent Application Publication
(10) Pub. No.: US 2013/0291798 A1
(43) Pub. Date: Nov. 7, 2013

(54) THIN FILM DEPOSITION APPARATUS AND SUBSTRATE TREATMENT SYSTEM INCLUDING THE SAME

(71) Applicants: Ho-Young Lee, Daejeon-si (KR); Sang-Joon Park, Yongin-si (KR); Jin-Pil Heo, Pyeongtaek-si (KR); Byung-Guk Son, Osan-si (KR); Wook-Sang Jang, Osan-si (KR); Kyung-Cheol Lee, Osan-si (KR)

(72) Inventors: Ho-Young Lee, Daejeon-si (KR); Sang-Joon Park, Yongin-si (KR); Jin-Pil Heo, Pyeongtaek-si (KR); Byung-Guk Son, Osan-si (KR); Wook-Sang Jang, Osan-si (KR); Kyung-Cheol Lee, Osan-si (KR)

(73) Assignee: WONIK IP CO., LTD., Pyeontaek-si (KR)

(21) Appl. No.: 13/979,462

(22) PCT Filed: Jan. 3, 2012
(86) PCT No.: PCT/KR2012/000039

§ 371 Date: Jul. 12, 2013

(30) Foreign Application Priority Data
Jan. 14, 2011 (KR) 10-2011-0004213

(51) Int. Cl. C23C 16/458

(52) U.S. Cl. CPC C23C 16/458; Y10S 901/43
USPC 118/730; 901/43

(57) ABSTRACT

The present invention relates to a thin film deposition apparatus and a substrate treatment system including same. The thin film deposition apparatus includes a deposition chamber, a susceptor, a rotation mechanism, an elevation member, and an elevation driving unit. The deposition chamber has an inner space in which a deposition process is performed. The susceptor is disposed within the deposition chamber, and a plurality of substrates is seated on a top surface of the susceptor. The elevation member is disposed above the susceptor to support a portion of each side of the substrates seated on the susceptor. When the elevation member is operated, the substrates are separated from the susceptor or seated on the susceptor. The elevation driving unit elevates the elevation member.

### TECHNICAL FIELD

The present invention relates to a thin-film deposition apparatus used in depositing a thin film on a substrate in fabricating a semiconductor, and a substrate treatment system including the thin-film deposition apparatus.

### BACKGROUND ART

In general, thin-film fabrication methods used in the semiconductor field may include chemical vapor deposition (CVD) and physical vapor deposition (PVD). In a CVD process, a gas mixture reacts on a heated substrate surface, and thereby resulting elements are deposited on the substrate surface. CVD methods may be classified into atmospheric CVD (APCVD), low pressure CVD (LPCVD), plasma enhanced CVD (PECVD), and metal organic CVD (MOCVD) depending on the type of material used as a precursor, a pressure imposed during processes, and method for transferring energy necessary for reaction, etc.

MOCVD process is generally used for single crystal growth of nitride semiconductors for light emitting diode. MOCVD is the deposition of a thin metal film on a heated substrate by introducing a source gas onto the substrate, wherein the source gas is acquired by vaporizing an organic metal compound that is a source material in liquid form.

A thin-film deposition apparatus employing MOCVD performs a process simultaneously on a number of substrates provided within the same chamber, in an effort to increase productivity. In this case, a susceptor within the chamber is configured to have the substrates situated along the circumference of the susceptor. Moreover, the respective substrates are rotated by the rotation of satellites and the susceptor also rotates, so as to deposit a thin film evenly on each upper surface of the substrates. That is, the thin film is evenly deposited of the upper surface of each substrate which is both rotated and revolved.

The substrates to be processed are loaded onto the susceptor and the substrates on which the process is completed are unloaded from the susceptor. To automate the loading and unloading of the substrate by use of a transfer robot, the substrate needs to be elevated or lowered in the loading or unloading process. However, it is difficult to install devices, such as, elevation pins, which are used to elevate or lower the substrates, at appropriate positions where the substrates are located because the susceptor and the satellites rotate, as described above. Hence, operators generally load and unload the substrates manually. Accordingly, skilled operators are needed, and low work efficiency due to manual operation becomes an issue.

### DETAILED DESCRIPTION OF THE INVENTION

### Technical Problem

The present invention aims to provide a thin-film deposition apparatus configured to move upward and downward substrates seated on a susceptor, thereby automating loading and unloading process of the substrates and increasing work efficiency, and a substrate treatment system including the thin-film deposition apparatus.

### Technical Solution

The present invention provides a thin-film deposition apparatus including: a deposition chamber configured to have an inner space in which to perform a deposition process; a susceptor disposed within the deposition chamber and having a top surface on which a plurality of substrates are seated; a rotation mechanism configured to rotate the susceptor; and an elevation member disposed above the susceptor to support a portion of each side of the substrates seated on the susceptor, and configured to separate the substrates from the susceptor or seat the substrates on the susceptor during elevation.

The present invention also provides a substrate treatment system including: a thin-film deposition apparatus configured to deposit a thin film on a substrate; and a transfer robot configured to horizontally move while supporting a substrate so as to supply the thin-film deposition apparatus with a substrate on which a deposition process is to be performed or to withdraw from the thin-film deposition apparatus a substrate on which a deposition process is completed, wherein the thin-film deposition apparatus comprises a deposition chamber configured to have an inner space in which to perform a deposition process, a susceptor disposed within the deposition chamber and having a top surface on which a plurality of substrates are seated, a rotation mechanism configured to rotate the susceptor, and an elevation member disposed above the susceptor to support a portion of each side of the substrates seated on the susceptor, and configured to separate the substrates from the susceptor or seat the substrates on the susceptor during elevation.

### Advantageous Effects

According to the present invention, the thin-film deposition apparatus is configured to elevate or lower substrates seated on a susceptor, thereby automating the loading and unloading process of the substrates by use of a transfer robot, and therefore, making it feasible to load and unload the substrates without the help of skilled operators, and increasing work efficiency.

### DESCRIPTION OF DRAWINGS

FIG. 1 is a side cross-sectional view illustrating a thin-film deposition apparatus according to an exemplary embodiment of the present invention.

FIG. 2 is a perspective view illustrating the thin film deposition apparatus excluding a deposition chamber.

FIG. 3 is an exploded perspective view of FIG. 2.

FIGS. 4 and 5 are side cross-sectional views illustrating a substrate which is elevated by an elevation member of FIG. 1.

FIG. 6 is a perspective view illustrating a substrate treatment system according to an exemplary embodiment of the present invention.

FIGS. 7 to 9 are side cross-sectional views illustrating a switch unit to switch a substrate on a substrate cart according to an exemplary embodiment of the present invention.

FIGS. 10 and 11 are side cross-sectional views illustrating a switch unit to switch a substrate on a substrate cart according to another exemplary embodiment of the present invention.

### MODE FOR INVENTION

Hereinafter, the present invention will be described in detail by explaining preferred embodiments of the invention with reference to the attached drawings.

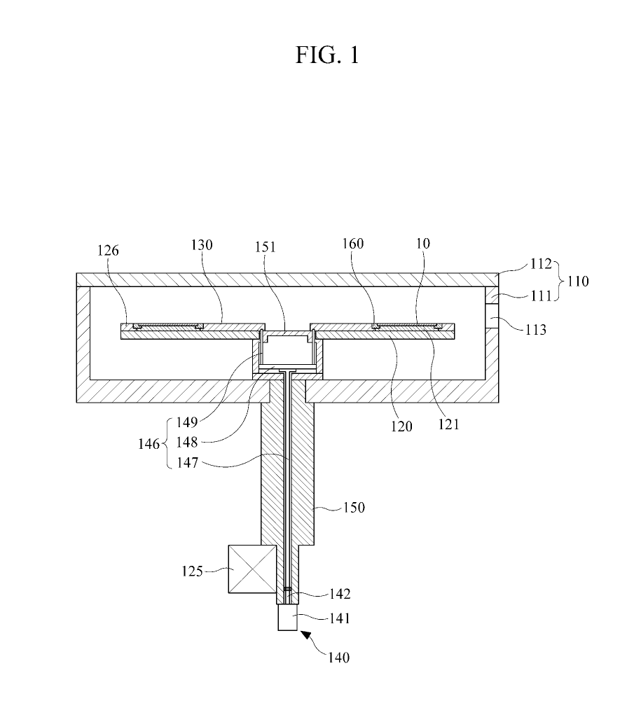

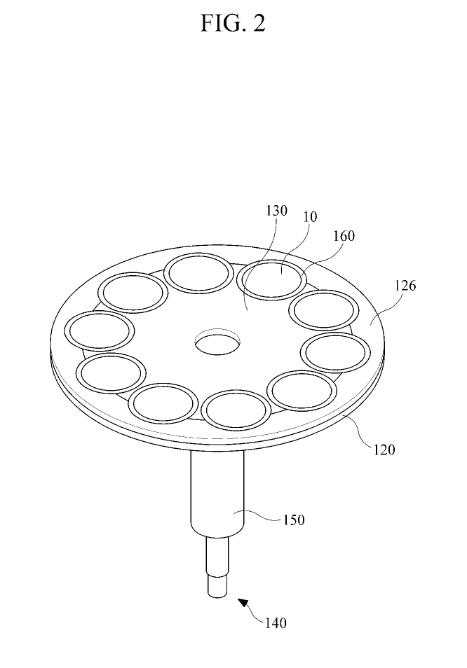

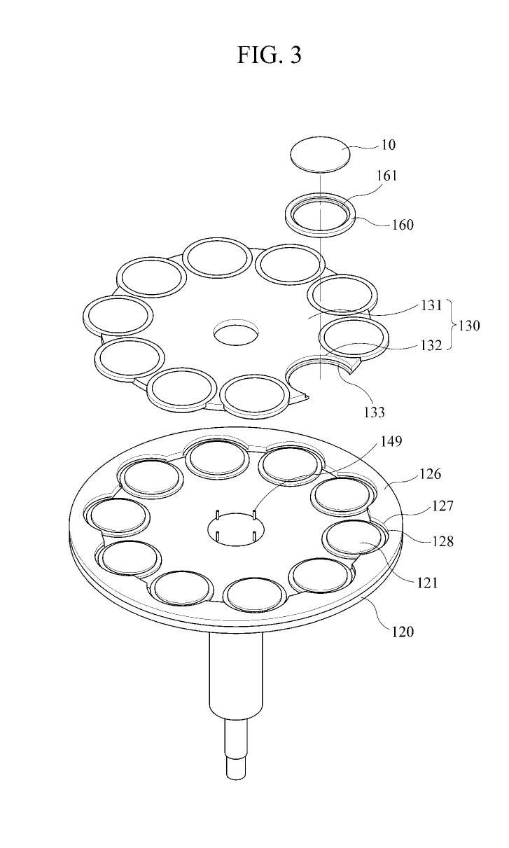

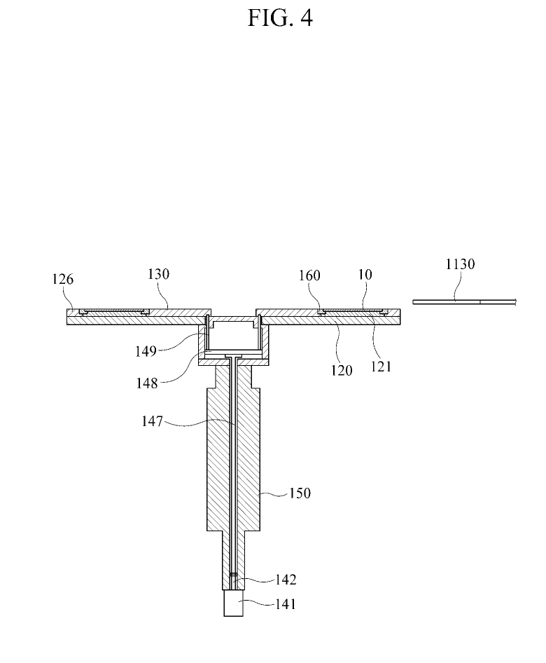

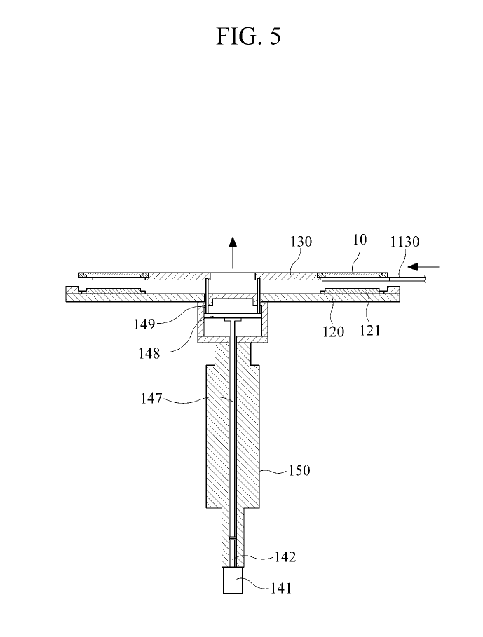

FIG. 1 is a side cross-sectional view illustrating a thin-film deposition apparatus according to an exemplary embodiment of the present invention. FIG. 2 is a perspective view illustrating the thin film deposition apparatus excluding a deposition chamber. FIG. 3 is an exploded perspective view of FIG. 2. FIGS. 4 and 5 are side cross-sectional views illustrating a substrate which is elevated by an elevation member of FIG. 1.

Referring to FIGS. 1 to 5, the thin-film deposition apparatus 100 for depositing a thin film on a substrate 10 may include a deposition chamber 110, a susceptor 120, a rotation mechanism 125, an elevation member 130, and an elevation driving unit 140. The thin-film deposition apparatus 100 may employ metal organic chemical vapor deposition (MOCVD) technique. In addition, the substrate 10 may be a wafer or glass substrate.

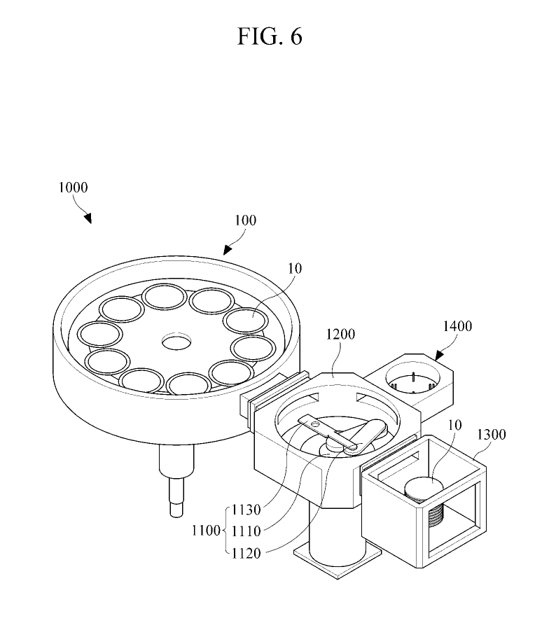

The deposition chamber 110 may have an inner space in which a deposition process takes place. The deposition chamber 110 may include a chamber body 110 with an open top and a top lid 110 to open and close the open top of the chamber body 111. The chamber body 111 may have a gate 113 formed on one side thereof to allow an end effector 1130 of a transfer robot 1100 (see FIG. 6) to enter and exit therethrough. The deposition chamber 110 may have a source gas supplying unit (not shown) installed therein. The source gas supplying unit may have first and second source gases introduced therein and then provide the received first and second source gases to the substrates 10 placed on the susceptor 120.

In the case of the deposition processing using group III-V MOCVD, the first source gas may contain the group V elements, and the second source gas may contain the group III elements. The first source gas may be a hydrogen compound containing the group V elements, which may be, for example, NH₃, PH₃, or AsH₃. The second source gas may be organic metal containing the group III elements, which may be, for example, TMG (Trimethylgallium), TEG (Triethylgallium), or TMI (Trimethylindium). The first and second source gases may each contain a carrier gas.

The susceptor 120 is disposed in the deposition chamber 110, and a plurality of substrates 10 are seated around a circumference of a top surface of the susceptor 120. This is to simultaneously make as many thin-film depositions on as many substrates 10 as possible, thereby facilitating mass production. The susceptor 120 may have seating portions on the top surface to allow the substrates 10 to be disposed at regular intervals along the circumference of the susceptor 120. The susceptor 120 may be supported by a susceptor support 150. The susceptor support 150 may be installed under the susceptor 120 to support a central portion of the susceptor 120.

The rotation mechanism 125 is provided to rotate the susceptor 120. In a case where a lower part of the susceptor support 150 extends out from the deposition chamber 110, the rotation mechanism 125 may be mounted on that extending part of the susceptor support 150. The susceptor 120 may rotate together with the susceptor support 150 which rotates by means of the rotation mechanism 125.

The elevation member 130 is disposed on the top surface of the susceptor 120. The elevation member 130 may support a portion of each side of the substrates 10 seated on the susceptor 120, and separate the substrates 10 from the susceptor 120 or seat the substrates 10 on the susceptor during an elevation. That is, the substrates 10 supported by the elevation member 130 may be elevated together with the rising elevation member 130.

The elevation member 130 may be formed to partially cover the top surface of the susceptor 120 to block the heat exerted on the top surface of the susceptor 120. The elevation member 130 may be made of one or more materials selected from quartz, graphite, and SiC. The elevation driving unit 140 elevates the elevation member 130.

Both the elevation member 130 and the elevation driving unit 140 enable the automation of the loading and unloading of the substrates 10 into and from the deposition chamber 110 by use of the transfer robot. For example, to provide the substrates 10 into the deposition chamber 110, the elevation member 130 may be lifted up from the top surface of the susceptor 120 by the elevation driving unit 140, as shown in FIG. 5.

In this state, outside of the deposition chamber 110, the end effector 1130 disposed on an end of an arm 1120 of the transfer robot 1100 loads the substrate 10 thereon and then horizontally moves to the top surface of the elevation member 130. Thereafter, the substrate 10 is transferred onto the elevation member 130 as the end effector 1130 moves down. The end effector 1130 returns to its original position to bring the next substrate 10, while the elevation member 130 is rotated together with the susceptor 120 so as to be placed at a position where the next substrate 10 can be transferred onto the elevation member 130. Then, the end effector 1130 transfers the next substrate 10 to the elevation member 130 through the above process. Once all substrates are transferred to the elevation member 130, the elevation member 130 is lowered to be in contact with the top surface of the susceptor 120 by the elevation driving unit 140, while supporting the portion of each side of substrates 10, as shown in FIG. 4. As a result, the substrates 10 are enabled to be seated on the susceptor 120.

In another example, the substrates 10 may be seated onto the susceptor 120 through the following process. When the end effector 1130 with the substrate 10 loaded thereon moves horizontally and is placed above the upper portion of the elevation member 130, the substrate 10 may be transferred to the elevation member 130 as the elevation member 130 moves upwards. The end effector 1130 then returns to its original position to bring the next substrate. The elevation member 130 moves downwards while rotating together with the susceptor 120 so as to be placed at a position to stand by for the next substrate 10 to be transferred. The elevation member 130 repeats the above procedures until all substrates 10 are transferred thereon. Once the transfer of all substrates 10 onto the elevation member 130 is complete, the elevation member 130 moves downward until it reaches the top surface of the susceptor 120, thereby enabling to load all substrates 10 onto the susceptor 120.

Meanwhile, to withdraw the substrates 10 from the deposition chamber 110, the elevation member 130 may be lifted up from the top surface of the susceptor 120 by the elevation driving unit 140 as shown in FIG. 5, while partially supporting the sides of each substrate 10 as shown in FIG. 4, so that the substrates 10 can be raised.

In this state, the end effector 1130 may horizontally move between the susceptor 120 and the elevation member 130. Then, the end effector 1130 elevates and receives the substrate 10 transferred from the elevation member 130. In another example, in a state in which the end effector 1130 moves and is placed between the susceptor 120 and the elevation member 130, the substrate 10 may be transferred to the end effector 1130 as the elevation member 130 moves downward. Then, the end effector 1130 withdraws the substrate 10 from the deposition chamber 110, and then returns to a position between the susceptor 120 and the elevation member 130. The end effector 1130 and the elevation member 130 repeat the above procedures until all substrates 10 are separated from the susceptor 120.

As described above, without installing elevation pins to each portion at which each of the substrates 10 is seated, it is possible to elevate the substrates 10 by use of the elevation member 130 and the elevation driving unit 140. The thin-film deposition apparatus 100 may be configured with satellites 121 on the substrate-seated portions to rotate the substrates 10 and may be configured to rotate the susceptor 120, such that a thin film can be deposited on the substrates 10 evenly. The loading and unloading of the substrates 10 to and from the susceptor 120 may be automated. Thus, the substrates 10 may be enabled to be loaded to and unloaded from the susceptor 120 without the help of skilled operators, and it is possible to increase work efficiency.

The elevation member 130 may include an elevation body portion 131 and substrate supporting portions 132. The elevation body portion 131 may be disposed at a position corresponding to a top central portion of the susceptor 120. Hence, the elevation body portion 131 is able to cover and protect the top central portion of the susceptor 120.

Each of the substrate supporting portions 132 may be formed by cutting along a circumference of the elevation body portion 131 to enclose a part of each substrate 10. For example, if the substrate 10 is disk-shaped, the substrate supporting portions 132 may be formed by cutting the elevation body portion 131 to a shape of an arc with an opening. The end effector 1130 vertically enters and exits through the substrate supporting portion 132 to transfer or receive the substrate to or from the elevation member 130. Here, the substrate supporting portion 132 may be formed in a shape of an arc with a central angle of 180 degrees or greater, such that it can enclose more than half of the circumference of the substrate 10. The central angle of the arc may vary within a range that allows the substrate supporting portion 132 to securely support the substrate 10.

The substrate supporting portions 132 each may include a step portion 133 on an inner surface to support a side of each substrate 10. The substrate 10 may be placed on and supported by the step portion 133 within the substrate supporting portion 132. The substrate supporting portions 132 may be disposed at a predetermined distance from the elevation body portion 131 while being arranged along the circumference of the elevation body portion 131 at regular intervals.

A protection member 126 may cover a remaining portion of the susceptor 120, other than the portion covered by the elevation member 130. The protection member 126 is fixed onto the top surface of the susceptor 120. The protection member 126 may have cut-grooves 127. Each of the cut-grooves 127 may be designed to encircle a circumferential part of the substrate 10 which is not enclosed by the elevation member 130. That is, each of the cut-grooves 127 may define the seating area of the substrate 10, together with the substrate supporting portion 132. In addition, a step 125 is provided on an inner surface of the substrate supporting unit 132 to support the substrate 10.

The substrates 10 may be supported directly by the substrate supporting portions 132, and also be indirectly supported by the substrate supporting portions 132 while being laid on substrate carts 160. In a case where each of the substrate carts 160 has an external diameter greater than a diameter of the substrate 10, the cut-portion of the substrate supporting portion 132 may be designed to extend to support a portion of each side of the substrate cart 160. Also, the cut-groove 127 may extend to support the remaining portion of the side of the substrate cart 160.

The substrate carts 160 have an opening in the middle, and a supporting landing 161 formed along an inner circumference of the opening. A bottom surface of the substrate 10 may be exposed when the substrate 10 is supported by the supporting landing 161 within the substrate cart 160. Thus, the substrate 10 may be rotated with the satellite 121 which touches the exposed bottom surface when the substrate 10 is placed on the susceptor 120 while being supported by the substrate cart 160.

The elevation driving unit 140 may include an elevation actuator 141 and a power delivery unit 146. The elevation actuator 141 may be, for example, an elevation cylinder. The elevation cylinder may be placed outside of the deposition chamber 110 and be mounted on a lower end of the susceptor support 150.

The power delivery unit 146 may deliver the power supplied from the elevation actuator 141 to the elevation member 130 through the susceptor support 150. Accordingly, the elevation member 130 may be able to stably elevate and descend by means of the power delivered from the power delivery unit 146 through the central part, that is, the elevation body portion 131. The power delivery unit 146 may be configured in various ways.

For example, the power delivery unit 146 may include an elevation shaft 147, an elevation disc 148, and elevation pins 149. The elevation shaft 147 may be provided with the power from the elevation actuator 141. The elevation shaft 147 may be installed to move upward and downward inside the susceptor support 150. The elevation actuator 141 is an elevation cylinder. In the case where the elevation cylinder is mounted on a lower end of the susceptor support 150, a rod 142 of the elevation cylinder may be coupled to the lower end of the elevation shaft 147. Accordingly, the elevation shaft 147 may move upward and downward along with the up and down movement of the rod 142 of the elevation cylinder.

The elevation disc 148 may be coupled to a top end of the elevation shaft 147. The elevation disc 148 may move up and down along with the up and down movement of the elevation shaft 147. The elevation disc 148 may be accommodated in a housing 151 installed above the susceptor support 150.

The elevation pins 149 each may have a lower end fixed onto a top surface of the elevation disc 148 or facing the top surface, and an upper end facing a bottom surface of the elevation member 130, that is, the elevation body portion 131. The elevation pins 149 may be arranged along a circumference of the elevation disc 148 at regular intervals with each other, in order to stably move the elevation member 130 upward and downward. The elevation pins 149 may not be fixed onto the bottom surface of the elevation member 130. In this case, the elevation pins 149 which are in contact with or separated downward from the elevation member 130 may be raised, thereby moving the elevation member 130 upward. It is also appreciated by those skilled in the art that the upper end of each of the elevation pins 149 may be fixed onto the bottom surface of the elevation member 130.

The satellites 121 may be disposed on the portions of the susceptor 120 where the respective substrates 10 are seated. The satellites 121 may be installed at positions corresponding to the bottom surfaces of the respective substrates 10 seated on the susceptor 120 and rotate the corresponding substrates 10. The substrates 10 are revolved by the rotation of the susceptor 120 and rotated by the rotation of the satellites 121. Consequently, it is possible to deposit a thin film evenly on the top surface of each substrate 10.

FIG. 6 is a perspective view illustrating a substrate treatment system according to an exemplary embodiment of the present invention. It is illustrated that a top of each chamber is open for convenience of description.

Referring to FIG. 6, the substrate treatment system 1000 may include a thin-film deposition apparatus 100 and a transfer robot 1100. The thin-film deposition apparatus 100 may deposit a thin film on a substrate 10, and may be configured as shown in FIGS. 1 to 5. The transfer robot 1100 may be operable to horizontally move a substrate 10 while holding it in order to provide the substrate 10 to the thin-film deposition apparatus 100 for a thin-film deposition to be performed, or in order to withdraw the substrate 10 from the thin-film deposition apparatus 100 after the thin-film deposition is completed.

The transfer robot 1100 may be installed inside a transfer chamber 1200. The transfer chamber 1200 may be connected with the deposition chamber 110 through gates. In addition, the transfer chamber 1200 may be connected through gates with a cassette chamber 1300 in which the substrates 10 are loaded.

The transfer robot 1100 may include a robot body 1110, an arm 1120 rotatably attached to the robot body 1110, and an end effector 1130 disposed on an end of the arm 1120. The arm 1120 may be operable to be horizontally spread out or folded up, thereby enabling the end effector 1130 to horizontally move. Hence, the end effector 1130 is enabled to transfer the substrate 10 while moving between the transfer chamber 1200 and the deposition chamber 110 or between the transfer chamber 1200 and the cassette chamber 1300.

In a case where each of the substrate carts 160 supports the substrate 10 seated thereon to provide the substrate 10 to the thin-film deposition apparatus 100, the substrate treatment system 1000 may further include a switch unit 1400. The switch unit 1400 may allow the transfer robot 1110 to switch the substrate 10 on the substrate cart 160 to another substrate 10, outside the deposition chamber 110. More specifically, in response to the substrate cart 160 with the substrate 10 seated thereon being transferred by the transfer robot 1100, the switch unit 1400 may allow the transfer robot to separate from the substrate cart 160 the substrate 10 on which the deposition process is completed, and to seat another substrate 10 to the substrate cart 160 for a deposition process to be performed thereon.

For example, the switch unit 1400 may include a switch chamber 1410, a plurality of vertical first pins 1420, a plurality of second vertical pins 1430, and a pin-elevation driving unit 1440, as shown in FIGS. 6 to 9. The substrate cart 160 has an opening in the middle, and a supporting landing 161 formed along an inner circumference of the opening to support a side of the substrate 10.

The switch chamber 1410 has a space in which to accommodate the substrate cart 160, and an exit 1411 through which to allow the end effector 1130 of the transfer robot 1100 to enter and exit. The exit 1411 is connected to the gate of the transfer chamber 1200, which allows the end effector 1130 to move between the switch chamber 1410 and the transfer chamber 1200.

The first vertical pins 1420 may be disposed within the switch chamber 1410 at positions corresponding to the central opening of the substrate cart 160. That is, in a state where the substrate 10 is seated on the substrate cart 160, the first vertical pins 1420 are disposed to face a bottom surface of the substrate 10. Then, the first vertical pins 1420 are moved upward.

The second vertical pins 1430 may be disposed to support the substrate cart 160 inside the switch chamber and may move upward. The second vertical pins 1430 may be placed outside of the first vertical pins 1420 at positions corresponding to the bottom surface of the substrate cart 160. The pin-elevation driving unit 1440 may elevate the first vertical pins 1420 and the second vertical pins 1430 independent of each other. The pin-elevation driving unit 1440 may include a first elevation bracket 1441 connected to lower ends of the first vertical pins 1420, a second elevation bracket 1442 connected to lower ends of the second vertical pins 1430, and an actuator 1443 to elevate the first elevation bracket 1441 and the second elevation bracket 1442 independent of each other.

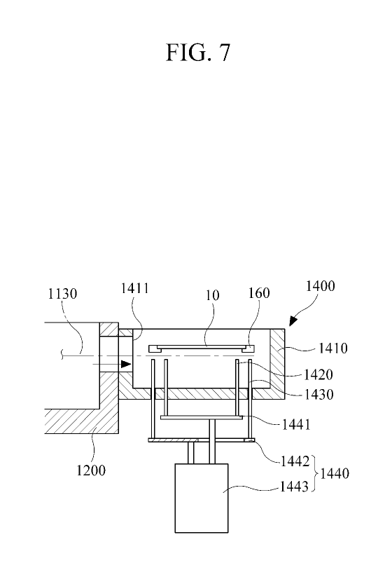

In this example, the process of switching the substrate 10 on the substrate cart 160 may be carried out as described below. As shown in FIG. 7, while the substrate cart 160 with the substrate 10 seated thereon is laid on the end effector 1130, the end effector 1130 moves horizontally above the first and second vertical pins 1420 and 1430. At this time, the end effector 1130 is placed at a position where the bottom surface of the substrate 10 is separated from the upper ends of the respective first vertical pins 1420, and the bottom surface of the substrate cart 160 is separated from the upper ends of the respective second vertical pins 1430.

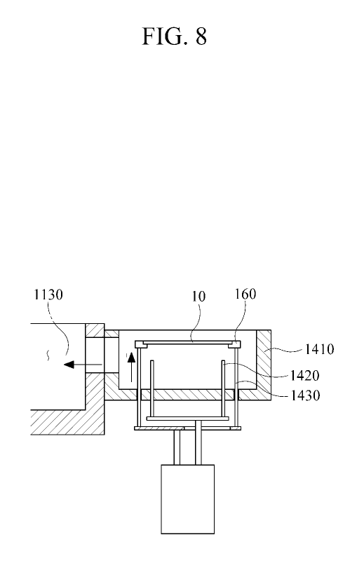

At this state, as shown in FIG. 8, the second vertical pins 1430 are elevated by the pin-elevation driving unit 1440 to push the substrate cart 160 upward, thereby enabling the substrate cart 160 to separate from the end effector 1130 in an upward direction.

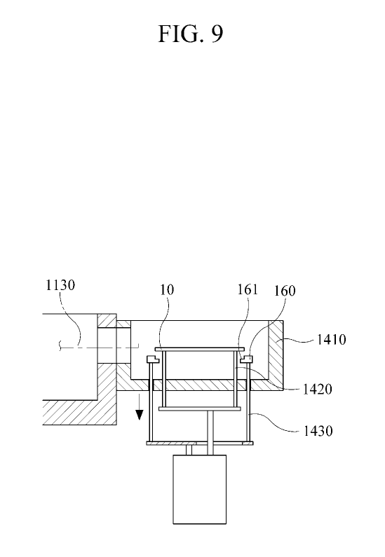

In response to the second vertical pins 1430 descending, as shown in FIG. 9, the substrate cart 160 may move downward together with the second vertical pins 1430 which have the upper ends supporting the substrate cart 160. At this time, when the substrate 10 comes in contact with the upper ends of the first vertical pins 1420, the substrate 10 stops moving downward. In this state, the second vertical pins 1430 move further downward to a height that allows the substrate cart 160 to separate from the substrate 10, and accordingly the substrate cart 160 and the substrate 10 is completely separated from each other.

The separated substrate 10 may be withdrawn from the switch chamber 1410 as described below. In a state where the substrate 10 is lifted up by elevating the first vertical pins 1420, the end effector 1130 moves horizontally to a position lower than a bottom surface of the substrate 10. Then, the substrate 10 is put on the end effector 1130 as first vertical pins 1420 descend. The end effector 1130 may withdraw the substrate 10 from the switch chamber 1410.

After the withdrawal of the substrate 10 from the switch chamber 1410, the end effector 1130 with a new substrate 10 loaded thereon moves horizontally above the first vertical pins 1420 to place the new substrate 10 above the upper ends of the respective first vertical pins 1420. Then, the first vertical pins 1420 elevate to lift up the new substrate 10, thereby separating the substrate 10 from the end effector 1130. Thereafter, the end effector 1130 moves horizontally away from the new substrate 10.

In this state, as the second vertical pins 1430 elevate, the substrate cart 160 also is pushed upward. When the substrate cart 160 is placed at an appropriate height, the new substrate 10 is seated on the substrate cart 160. In addition, the second vertical pins 1430 may be raised to a position where the bottom surface of the substrate cart 160 is higher than a top surface of the end effector 1130. The end effector 1130 may then horizontally move to a position lower than the bottom surface of the substrate cart 160. In this state, as the second vertical pins 1430 move downward, the substrate cart 160 is put on the end effector 1130, and then the second vertical pins 1430 are separated downward from the substrate cart 160. At this time, the first vertical pins 1420 may be placed in order to be separated downward from the bottom surface of the substrate. Thereafter, the end effector 1130 withdraws from the switch chamber 1410 the substrate cart 160 on which the new substrate 10 is seated.

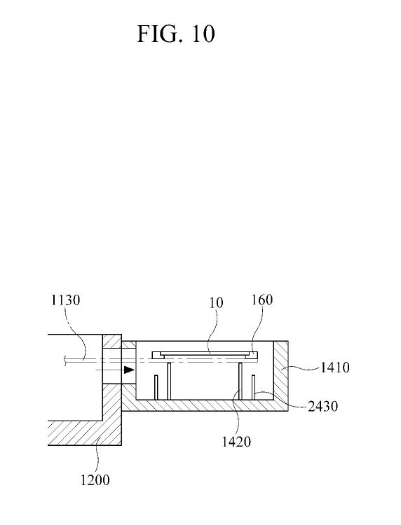

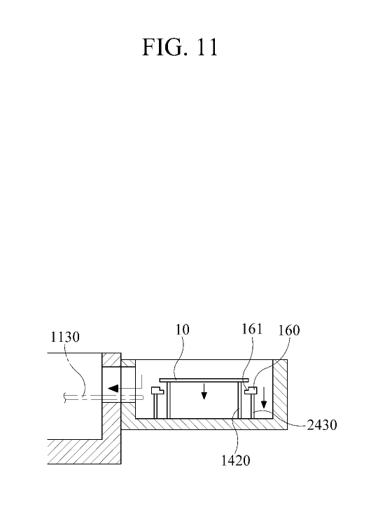

In another example, the switch unit 1400 may be configured as shown in FIGS. 10 and 11. The plurality of second vertical pins 2430 may have a height lower than that of the first vertical pins 1420. Here, the transfer robot 1100 may be configured to move horizontally and also move upward and downward while supporting the substrate 10 thereon.

In this example, the switching process of the substrate 10 on the substrate cart 160 may be carried out as described below. As shown in FIG. 10, while the substrate cart 160 having the substrate 10 seated thereon is laid on the end effector 1130, the end effector 1130 moves horizontally above the first and second vertical pins 1420 and 1430. At this time, the end effector 1130 is placed at a position where the bottom surface of the substrate 10 is separate from upper ends of the respective first vertical pins 1420, and the bottom surface of the substrate cart 160 is separated from the upper ends of the respective second vertical pins 1430.

Thereafter, as the end effector 1130 moves downward while supporting the bottom surface of the substrate cart 160, both the substrate cart 160 and the substrate 10 move downward, as shown in FIG. 11. At this time, when the substrate 10 is in contact with the upper ends of the first vertical pins 1420, the substrate 10 stops descending. In this state, when the end effector 1130 is further lowered to a height at which the substrate cart 160 makes contact with the upper ends of the respective second vertical pins 2430, the substrate cart 160 is enabled to be separated from the substrate 10. The end effector 1130 moves further downward to be separated downward from the substrate cart 160, and moves horizontally away from the substrate cart 160. The substrate 10 separated from the substrate cart 160 is lifted up by the end effector 1130 and withdrawn from the switch chamber 1410.

Thereafter, the end effector 1130 may load a new substrate 10 thereon, and place the substrate 10 to touch the upper ends of the respective first vertical pins 1420. The end effector 1130, then, moves downward to support and lift up the substrate cart 160 on the upper ends of the second vertical pins 2430, and then moves up while supporting the substrate cart 160. During these procedures, as the substrate cart 160 elevates, the new substrate 10 is seated on the substrate cart 160. Then, the end effector 1130 lifts up the substrate cart 160 to a height at which the new substrate 10 can be separated from the upper ends of the first vertical pins 1420, and withdraws the substrate 10 from the switch chamber 1410.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

1. A thin-film deposition apparatus comprising:
a deposition chamber configured to have an inner space in which to perform a deposition process;
a susceptor disposed within the deposition chamber and having a top surface on which a plurality of substrates are seated;
a rotation mechanism configured to rotate the susceptor; and
an elevation member disposed above the susceptor to support a portion of each side of the substrates seated on the susceptor, and configured to separate the substrates from the susceptor or seat the substrates on the susceptor during elevation.

2. The thin-film deposition apparatus of claim 1, wherein the elevation member comprises an elevation body portion disposed at a position corresponding to a top central portion of the top surface of the susceptor, and substrate supporting portions, each being formed by cutting along a circumference of the elevation body portion to enclose a part of each substrate and having a step portion on an inner surface thereof to support the side of each substrate.

3. The thin-film deposition apparatus of claim 1, wherein the elevation member is made of one or more materials selected from quartz, graphite, and SiC.

4. The thin-film deposition apparatus of claim 1, further comprising:
substrate carts, on each of which to load and support the substrate,
wherein the elevation member is formed to support a portion of each side of the substrate carts.

5. The thin-film deposition apparatus of claim 4, wherein each of the substrate carts has an opening in a middle thereof, and a supporting landing formed along an inner circumference of the opening.

6. The thin-film deposition apparatus of claim 1, wherein the elevation driving unit comprises an elevation actuator and a power delivery unit configured to deliver power from the elevation actuator to the elevation member.

7. The thin-film deposition apparatus of claim 1, further comprising:
satellites configured to rotate, respectively, the substrates seated on the susceptor.

8. A substrate treatment system comprising:
a thin-film deposition apparatus configured to deposit a thin film on a substrate; and
a transfer robot configured to horizontally move while supporting a substrate so as to supply the thin-film deposition apparatus with a substrate on which a deposition process is to be performed or to withdraw from the thin-film deposition apparatus a substrate on which a deposition process is completed,
wherein the thin-film deposition apparatus comprises
a deposition chamber configured to have an inner space in which to perform a deposition process,
a susceptor disposed within the deposition chamber and having a top surface on which a plurality of substrates are seated,
a rotation mechanism configured to rotate the susceptor, and
an elevation member disposed above the susceptor to support a portion of each side of the substrates seated on the susceptor, and configured to separate the substrates from the susceptor or seat the substrates on the susceptor during elevation.

9. The substrate treatment system of claim 8, further comprising:
substrate carts, on each of which to load and support the substrate; and
a switch unit configured to allow the transfer robot to switch the substrate on the substrate cart to another substrate, outside of the deposition chamber.

10. The substrate treatment system of claim 9, wherein each of the substrate carts has an opening in a middle thereof and a supporting landing formed along an inner circumference of the opening to support a side of each substrate,
and the switch unit comprises
a switch chamber having space in which to accommodate the substrate cart and an exit through which to allow an end of an arm of the transfer robot to enter and exit,
a plurality of first vertical pins disposed within the switch chamber at positions corresponding to the opening in the middle of the substrate cart and configured to move upward and downward,
a plurality of second vertical pins disposed within the switch chamber to support the substrate cart and configured to move upward and downward, and
a pin-elevation driving unit configured to elevate the first and second vertical pins independent of each other.

11. The substrate treatment system of claim 9, wherein each of the substrate carts has an opening in a middle thereof, and a supporting landing formed along an inner circumference of the opening to support a side of each substrate,
the switch unit comprises
a switch chamber having space in which to accommodate the substrate cart and an exit through which to allow an end of an arm of the transfer robot to enter and exit,
a plurality of first vertical pins disposed within the switch chamber at positions corresponding to the opening in the middle of the substrate cart, and
a plurality of second vertical pins disposed within the switch chamber to support the substrate cart and having a height lower than that of the first vertical pins, and
the transfer robot is operable to move upward and downward while supporting the substrate.

12. The substrate treatment system of claim 8, wherein the elevation member comprises an elevation body portion disposed at a position corresponding to a top central portion of the top surface of the susceptor, and substrate supporting portions, each being formed by cutting along a circumference of the elevation body portion to enclose a part of each substrate and having a step portion on an inner surface thereof to support the side of each substrate.
